(19) United States
(12) Patent Application Publication
(10) Pub. No.: US 2011/0221312 A1
(43) Pub. Date: Sep. 15, 2011

(54) VIBRATOR ELEMENT, VIBRATOR, SENSOR, AND ELECTRONIC APPARATUS

(75) Inventor: Ryuta NISHIZAWA, Suwa (JP)

(73) Assignee: SEIKO EPSON CORPORATION, Tokyo (JP)

(21) Appl. No.: 13/042,783

(22) Filed: Mar. 8, 2011

(30) Foreign Application Priority Data
Mar. 12, 2010 (JP) 2010-055446
Dec. 6, 2010 (JP) 2010-271220

(51) Int. Cl. H01L 41/04

(52) U.S. Cl. 310/370

(57) ABSTRACT

A vibrator element includes: a base portion; a vibrating arm that extends in a first direction from the base portion, has a width in a second direction perpendicular to the first direction in the plan view, and has a thickness in a third direction perpendicular to the first direction and the second direction; and an inter digital transducer, in which electrode fingers are arranged in the first direction, disposed at least one of a first surface, which is perpendicular to the third direction, and a second surface, which faces the first surface, of the vibrating arm, wherein the vibrating arm is vibrated in the third direction by stretching or contacting the vibrating arm in the first direction by using an electric field in the first direction that is generated by the inter digital transducer.

### BACKGROUND

1. Technical Field

The present invention relates to a vibrator element, a vibrator, a sensor, and an electronic apparatus.

2. Related Art

A vibrator element is a vibrating member that becomes a constituent element such as a vibrator or a sensor device. For example, the vibrator element has a base portion and a vibrating arm (vibrating beam) that is joined with (connected to) the base portion.

For example, when an voltage (electric field) is applied to quartz crystal as a piezoelectric body (piezoelectric material), the quartz crystal is deformed. The quartz crystal has inductive reactance such as a coil only for a specific frequency band close to its natural frequency.

An electronic component using this principle is a quartz crystal vibrator. The quartz crystal vibrator is manufactured by housing a quartz crystal vibrator element in a package and, for example, performing air-sealing for the inside of the package. The quartz crystal vibrator, for example, is used as a constituent component of an oscillation circuit.

In addition, a vibrator element (for example, a twin resonance tuning fork-type vibrator element) having a two-side supporting structure in which both ends of the vibrating arm are supported by the base portion can be used as a sensor device (for example, a force detecting device) that is used for detecting a physical amount (acceleration, pressure, or the like).

Since quartz crystal has superior temperature stability and a high Q value, by using a quartz crystal vibrator, a sensor, which has high precision and high stability, having high reliability can be realized.

An example of the vibrator is disclosed in JP-A-2001-144581. In the vibrator disclosed in JP-A-2001-144581, the vibrator element vibrates in the direction (in a case where the vibrator element extends in a first direction, a second direction that is perpendicular to the first direction in the same plane) of the width of the vibrator element.

In addition, an example in which an inter digital transducer is used in a vibrator element is disclosed in JP-A-2004-151031 and JP-A-2003-114127. The inter digital transducer disclosed in JP-A-2004-151031 and JP-A-2003-114127 is an electrode having a peculiar shape that serves as a driving electrode and a detection electrode for a gyro sensor. The shape of the inter digital transducer is a shape in which the direction of polarization of a predetermined portion of a piezoelectric mono-crystal can be easily formed to be opposite to (inverting) the direction of the polarization of the entire piezoelectric mono crystal.

In addition, recently, by using MEMS technology or the like, reduction of the size of the vibrator element to a large extent is considered.

The resonance frequency can be represented in the following Equation (1) in a case where a vibrating arm of a vibrator element as a constituent element of a vibrator vibrates in the direction of the width (horizontal width) of the vibrating arm (an example disclosed in JP-A-2001-144581).

$$fn = α \cdot \frac{w}{{l}^{2}} \sqrt{\frac{E}{12 {ρ}_{res}}} \qquad ( 1 )$$

wherein α is a constant decided according to the supporting condition, w is the width of a vibrating arm (arm width), l is the length of the vibrating arm (arm length), E is the elastic constant of the vibrating arm (Young's modulus), and Pᵣₑₛ is the density of the vibrating arm.

Under the condition in which the resonance frequency fn is maintained as constant, in a case where the vibrator element is miniaturized by shortening the arm length l of the vibrating arm, from the above-described Equation (1), the width (arm width) w of the vibrating arm needs to be decreased. In a case where the arm width w is decreased, the width of each electrode or a gap between the electrodes is shortened.

Accordingly, there is a case where it is difficult to form electrodes, and a case where the yield ratio decreases. This point is a problem common to the vibrator element disclosed in JP-A-2001-144581, JP-A-2004-151031, and JP-A-2003-114127.

In addition, in the case of the inter digital transducer having a peculiar shape as described in JP-A-2004-151031 and JP-A-2003-114127, as the arm width w of the vibrating arm is further decreased, the electric field in the width direction of the vibrating arm becomes dominant more than the electric field in the direction of extension of the vibrating arm, and the efficiency of the electric field decreases. Accordingly, there is also a problem in that a C1 value (a value of crystal impedance) increases.

### SUMMARY

An advantage of some aspects of the invention is that it reduces the burden at the time of forming electrodes or wirings that is accompanied with miniaturization of the vibrator element.

(1) According to a first aspect of the invention, there is provided a vibrator element including: a base portion; a vibrating arm that extends in a first direction from the base portion, has a width in a second direction perpendicular to the first direction in the plan view, and has a thickness in a third direction perpendicular to the first direction and the second direction; and an inter digital transducer, in which electrode fingers are arranged in the first direction, disposed at least one of a first surface, which is perpendicular to the third direction, and a second surface, which faces the first surface, of the vibrating arm. The vibrating arm is vibrated in the third direction by stretching or contacting the vibrating arm in the first direction by using an electric field in the first direction that is generated by the inter digital transducer.

In this aspect, the vibrating arm of the vibrator element vibrates in a third direction (the out-of-plane direction: the direction of the thickness of the vibrating arm) perpendicular to a predetermined surface. In other words, vibration of the work mode is excited in the vibrating arm. The resonance frequency of the vibrator element for this case can be represented in the following Equation (2).

$$fn = α \cdot \frac{t}{{l}^{2}} \sqrt{\frac{E}{12 {ρ}_{res}}} \qquad ( 2 )$$

wherein α is a constant decided according to the supporting condition, t is the thickness of a vibrating arm, l is the length of the vibrating arm (arm length), E is the elastic constant of the vibrating arm (Young's modulus), and Pᵣₑₛ is the density of the vibrating arm.

As is apparent from the above-described Equation (2), as a condition for maintaining the resonance frequency to be constant, in a case where the arm length l of the vibrating arm is shortened, the thickness t of the vibrating arm is decreased. Accordingly, reasonable downsizing of the vibrating arm can be realized.

The thickness t of the vibrating arm can be controlled with precision higher than that of the arm width w of the vibrating arm by adjusting the thickness of the piezoelectric material plate configuring the vibrator element.

In addition, for example, by using an inter digital transducer (IDT (inter-digital transducer) electrode), an electric field in the direction (the first direction) of extension of the vibrating arm can be generated so as to excite the vibrating arm in the out-of-plane direction.

(2) According to a second aspect of the invention, in the above-described vibrator element, when the width of the vibrating arm is w, and the thickness is t, a condition of “w>t” is satisfied.

According to the first aspect of the invention, the arm width w of the vibrating arm does not need to be decreased in accordance with the scale-down of the arm length l. Accordingly, the arm width w of the vibrating arm can be maintained, for example, at a size, for which electrodes or wirings can be formed with high reliability. Accordingly, a condition of the arm width w of the vibrating arm >the thickness t of the vibrating arm can be satisfied.

Accordingly, from the viewpoint that the arm width w of the vibrating arm can be set to an appropriate value while decreasing the thickness t of the vibrating arm, the concern about defective formation (disconnection or a contact) of wirings or electrodes disappears. Accordingly, the burden at the time of formation of electrodes and wirings, which is accompanied with the miniaturization of the vibrator element, can be decreased.

In addition, since the thickness t of the vibrating arm can be controlled with high precision, the resonance frequency of the vibrator element can be adjusted with high precision. For example, when a piezoelectric material plate, which becomes the base material of the vibrator element, is cut out from a piezoelectric mono crystal (quartz crystal or the like), the thickness t of the piezoelectric material plate can be adjusted, and the thickness t can be also adjusted through a polishing process after the cutting out of the piezoelectric material plate or the like.

In any of the cases, the parallelism between the front surface (the first surface) of the piezoelectric material plate and the rear surface (the second surface) can be controlled as high, and the thickness t can be controlled with high precision.

(3) According to a third aspect of the invention, in the above-described vibrator element, quartz crystal is used for the vibrator element, and the first direction is an X-axis direction of the crystal axis of the quartz crystal, the second direction is a Y-axis direction of the crystal axis of the quartz crystal, and the third direction is a Z-axis direction of the crystal axis of the quartz crystal.

In this aspect, quartz crystal as a piezoelectric material plate is used for the vibrator element, and the vibrator element vibrates in the direction (the third direction or the Z-axis direction of the crystal axis of the quartz crystal) perpendicular to a plane including the Z surface (a surface that is defined by the X-axis and the Y-axis of the crystal axis of quartz crystal) vibrates in the out-of-plane. The out-of-plane vibration can be excited by using a piezoelectric constant (a piezoelectric constant d11 that generates distortion Sx in the X-axis direction for the electric field applied in the X-axis direction) that generates distortion in the first direction (the X-axis direction or the direction of extension of the vibrating arm) that is included in quartz crystal.

(4) According to a fourth aspect of the invention, in the above-described vibrator element, when a distance between one electrode finger and another electrode finger adjacent to one side of the electrode finger is L1, and a distance between the electrode finger and another electrode finger adjacent to the other side of the electrode finger is L2, L2 is greater than L1 in the inter digital transducer.

In this aspect, a case will be considered in which the inter digital transducer, for example, has a first opposing portion configured by one pair of electrode fingers arranged so as to face each other with a predetermined distance separated from each other and a second opposing portion that is adjacent to the first opposing portion and is configured by one pair of electrode fingers arranged so as to face each other with a predetermined distance separated from each other.

In each of the first opposing portion and the second opposing portion, an electric field (effective electric field) is generated between one pair of electrode fingers facing each other, and this electric field (effective electric field) is applied to the vibrating arm. On the other hand, an electric field (ineffective electric field) is also generated between the electrode finger of the first opposing portion that is disposed on the second opposing portion side and the electrode finger of the second opposing portion that is disposed on the first opposing portion side.

At this time, in a case where the direction of the effective electric field that is generated in each of the first opposing portion and the second opposing portion and the direction of the ineffective electric field generated between the first opposing portion and the second opposing portion are opposite to each other, there is a problem in that a part of the effective electric field is negated by the ineffective electric field.

Accordingly, in this aspect, the distance between the first opposing portion and the second opposing portion, that is, the distance L2 between one electrode finger and another electrode finger adjacent to one side of the one electrode finger is set to be longer than the distance between the electrode fingers of each of the first opposing portion and the second opposing portion, that is, the distance L1 between the one electrode finger and another electrode finger adjacent to the other side of the one electrode.

Accordingly, a phenomenon that the effective electric field is negated by the electric field generated between the first opposing portion and the second opposing portion can be reduced.

(5) According to a fifth aspect of the invention, in the above-described vibrator element, when a distance between one electrode finger disposed near an end of the base portion of the vibrating arm and another electrode finger adjacent to one side of the one electrode is L1, and a distance between the one electrode finger and another electrode finger adjacent to the other side of the electrode finger is L2, L2 is greater than L1, when a distance between one electrode finger disposed near a front end portion of the vibrating arm and another electrode finger adjacent to one side of the one electrode is L3, and a distance between the one electrode finger and another electrode finger adjacent to the other side of the electrode finger is L4, L4 is greater than L3, and L4 is greater than L2.

In order to generate out-of-plane vibration in the vibrating arm, stress (distortion) of contracting (compressing) or stretching (pulling) needs to occur in at least one of the first surface (the front surface) and the second surface (the rear surface) of the vibrating arm.

Since the vibrating arm vibrates in the third direction with the base portion as a fixed end used as a reference, distortion that is the most effective for the flexion of the vibrating arm is distortion occurring in a place that is close to the base portion.

Accordingly, distortion occurring in a place (near the front end portion) located far from the base portion has a little influence on the flexion of the vibrating arm.

Based on this consideration, in this aspect, the distance between the electrode fingers included in the inter digital transducer is changed in accordance with the distance from the base portion. In other words, the distance L4 between the electrode fingers near the front end portion is set to be longer than the distance L2 between the electrode fingers near the end of the base portion.

Accordingly, the number of the opposing portions arranged along the direction of extension of the vibrating arm can be set to be smaller than that of a case where the opposing portions are arranged so as to be equally spaced. This represents that a total amount of the electric fields generated in the vibrating arm decreases, and accordingly, an effect of reducing the power consumption can be acquired.

On the other hand, even when an electric field in a place located far from the base portion decreases, the degree of contribution of the electric field to the flexion of the vibrating arm is low, and accordingly, out-of-plane vibration of the desired amplitude can be generated in the vibrating arm.

(6) According to a sixth aspect of the invention, in the above-described vibrator element, the inter digital transducer is disposed on the first surface and the second surface, and the directions of the electric fields are opposite to each other in a first inter digital transducer disposed on the first surface and in a second inter digital transducer disposed on the second surface.

According to this configuration, the direction of the generated electric field is opposite in the first inter digital transducer disposed on the first surface and the second inter digital transducer disposed on the second surface. Accordingly, the direction of generated distortion is opposite therein.

Therefore, according to this aspect, the out-of-plane vibration (the vibration of the work mode in the third direction, that is, the Z-axis direction) of the vibrator element can be efficiently excited.

(7) According to a seventh aspect of the invention, in the above-described vibrator element, in the first inter digital transducer and the second inter digital transducer, the electrode fingers having different polarities do not overlap each other in the third direction in the plan view.

According to this configuration, since the electrode fingers having different polarities do not overlap each other in the first inter digital transducer and the second inter digital transducer in the plan view in the third direction, unnecessary generation of electric fields in the third direction can be suppressed.

(8) According to an eighth aspect of the invention, in the above-described vibrator element, a concave portion is disposed on at least one of the first surface and the second surface of the vibrating arm, and the electrode fingers configuring the inter digital transducer are disposed on each of both side surfaces of the convex portions that are perpendicular to the first direction.

According to this configuration, the electrode fingers are disposed on each of both side surfaces perpendicular to the first direction of the convex portion. Accordingly, the electric fields in directions other than the first direction decrease, and the out-of-plane vibration can be excited more efficiently.

Since the permittivity of the air is lower than that of the material (quartz crystal or crystal) of the vibrating arm, the ineffective electric field generated between the convex portions adjacent to each other with a space interposed therebetween is weakened.

Therefore, a phenomenon of negation of the effective electric field with the ineffective electric field can be effectively reduced. This point also contributes to effective excitation of the out-of-plane vibration.

(9) According to a ninth aspect of the invention, in the above-described vibrator element, a plurality of the vibrating arms is disposed.

According to this configuration, a plurality of vibrating arms is disposed, and the vibrating arms are vibrated, for example, in a dynamic balance. Therefore, the out-of-plane vibration of the vibrating arm can be further stabilized.

(10) According to a tenth aspect of the invention, in the above-described vibrator element, the base portion includes a first base portion and a second portion, and one end of the vibrating arm and the first base portion are connected to each other, and the other end of the vibrating arm and the second base portion are connected to each other.

According to this configuration, the vibrator element is a vibrator element, in which both ends of the vibrating arms are supported by each base portion, having a two-side supporting structure. The vibrator element having the two-side supporting structure can be appropriately used, for example, as a constituent element of an acceleration sensor or a pressure sensor.

(11) According to an eleventh aspect of the invention, there is provided a vibrator including: the vibrator element according to any one of the above-described aspects; and a housing body that houses the vibrator element.

According to this configuration, this aspect includes the vibrator element according to any of the above-described aspects, and accordingly, a miniaturized vibrator that can be oscillated with high precision can be realized.

(12). According to a twelfth aspect, there is provided a sensor including: the vibrator element according to any one of the above-described aspects.

According to this configuration, this aspect includes the vibrator element according to any of the above-described aspects. Therefore, a miniaturized sensor (a pressure sensor, an acceleration sensor, or the like), which uses the vibrator element that can be oscillated with high precision, having high precision can be realized.

For example, by fixing both ends of the vibrator element having the two-side supporting structure to a diaphragm as an elastic portion, the pressure sensor can be formed.

In addition, by fixing one end of the vibrator element having the two-side supporting structure to the mass portion (pendulum portion), an acceleration sensor can be formed.

(13) According to a thirteenth aspect of the invention, there is provided an electronic apparatus including the vibrator element according to any one of the above-described aspects.

According to this configuration, this aspect includes the vibrator element according to any of the above-described aspects. Therefore, a miniaturized electronic apparatus, for example, having a miniaturized sensor having high precision can be provided.

### BRIEF DESCRIPTION OF THE DRAWINGS

The invention will be described with reference to the accompanying drawings, wherein like numbers reference like elements.

FIGS. 1A to 1D are schematic diagrams illustrating an example of the configuration and the operation of a vibrator element.

FIGS. 2A to 2C are diagrams showing an example of the configuration of an inter digital transducer.

FIG. 3 is a schematic diagram illustrating the excitation of out-of-plane vibration of a vibrating arm.

FIG. 4 is a diagram showing another example of the configuration of an inter digital transducer.

FIG. 5 is a diagram showing still another example of the configuration of an inter digital transducer.

FIGS. 6A and 6B are diagrams showing an example in which a plurality of vibrating arms is arranged.

FIG. 7 is a diagram illustrating an example of a manufacturing process of a vibrator using a vibrator element.

FIGS. 8A and 8B are schematic diagrams illustrating examples of out-of-plane vibration of a vibrator element having a two-side supporting structure and the arrangement of electrodes.

FIGS. 9A to 9C are diagrams showing examples of the configuration of a vibrator element having a two-side supporting structure.

FIGS. 10A and 10B are diagrams showing examples of the arrangement of electrodes and wirings of a twin resonance tuning fork-type vibrator element having three vibrating arms.

FIGS. 11A and 11B are diagrams showing examples of the structures of an acceleration sensor device and an acceleration sensor that use a twin resonance tuning fork-type vibrator element.

### DESCRIPTION OF EXEMPLARY EMBODIMENTS

### First Embodiment

Example of Structure and Operation of Vibrator element Using Out-of-plane Vibration

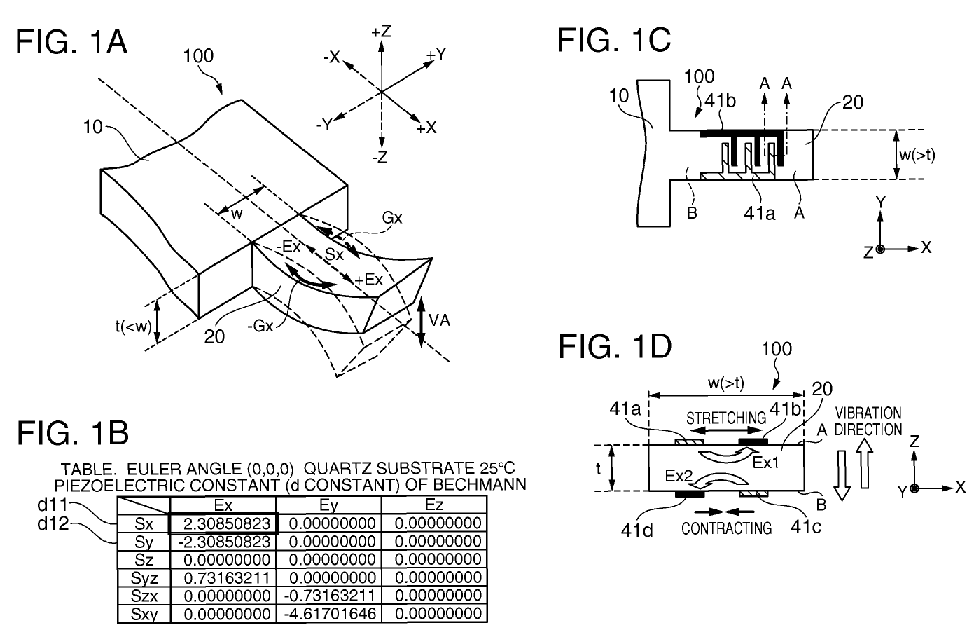

FIGS. 1A to 1D are schematic diagrams illustrating an example of the configuration and the operation of a vibrator element according to a first embodiment of the invention.

As shown in FIG. 1A, the vibrator element 100 includes a base portion 10 and a vibrating arm 20 that extends from the base portion 10 in a first direction (the X-axis direction) within a predetermined plane (within an XY plane that is defined by the X axis and the Y axis).

The vibrator element 100, for example, is formed by a piezoelectric material plate. In this embodiment, the vibrator element 100 is formed by using a Z plate (including an approximate Z plate) of quartz crystal crystal. For example, the predetermined plane (the XY plane) described above is a plane that includes a Z plane of quartz crystal. Hereinafter, a case where the Z plane of quartz crystal is used will be described as an example.

The vibrating arm 20 has a predetermined width w in a second direction (the Y-axis direction of the quartz crystal crystal axis) that is perpendicular to the first direction (the X-axis direction of the quartz crystal crystal axis) in the plan view and a predetermined thickness t in a third direction (the Z-axis direction of the quartz crystal crystal axis) that is a direction perpendicular to the first and second directions.

The width (arm width) w of the vibrating arm 20 in the second direction and the thickness t in the third direction satisfy the relationship of “w>t”.

In this embodiment, the vibrating arm 20 vibrates in the third direction. In other words, the vibrating arm 20 makes out-of-plane vibration in the direction perpendicular to the predetermined plane.

This out-of-plane vibration is excited in accordance with a piezoelectric constant d11 of the quartz crystal as a piezoelectric material that generates distortion Sx in the first direction for an electric field applied in the first direction (the X-axis direction).

FIG. 1B is a diagram representing the relationship between the piezoelectric constant of the quartz crystal plate and the electric field and the distortion.

As represented in FIG. 1B, the quartz crystal plate (the Z plate) has a piezoelectric constant d11 (+2.30850823) that generates distortion Sx in the first direction for an electric field Ex applied in the first direction (the X-axis direction) and has a piezoelectric constant d12 (−2.30850823) that generates distortion Sy in the second direction (the Y-axis direction) for the electric field Ex applied in the first direction.

The sign of the piezoelectric constant d11 corresponding to the distortion Sx is positive. Thus, when the electric field +Ex is generated in the positive first direction (+X-axis direction), stretching stress (pulling stress) is generated. Since the value of the piezoelectric constant d1 1 corresponding to the distortion Sx is sufficiently great, desired out-of-plane vibration can be excited in the vibrating arm 20 by using the piezoelectric constant d11.

Described in detail, as illustrated in FIG. 1A, when an electric field +Ex in the +X-axis direction is generated, stretching stress is generated due to distortion Sx, and the vibrating arm 20 is bent such that the tip end thereof is displaced in the −Z-axis direction, as denoted by a broken-line arrow Gx.

On the other hand, when an electric field −Ex in the +X-axis direction is generated, contracting stress (compressing stress) is generated due to distortion Sx, and the vibrating arm 20 is bent such that the tip end thereof is displaced in the +Z-axis direction, as denoted by an arrow −Gx.

According to the above-described operations, by alternately changing the direction (−X-axis direction and the +X-axis direction) of application of the electric field Ex in the X-axis direction, out-of-plane vibration VA in the Z-axis direction can be generated in the vibrating arm 20.

FIG. 1C shows the shape of the vibrator element in the plan view viewed in the positive third direction. FIG. 1D is a cross-sectional view of the vibrator element taken along line A-A shown in FIG. 1C.

In order to excite out-of-plane vibration in the vibrating arm 20, an electric field Ex in the first direction (the X-axis direction) needs to be generated in at least one of a first surface A (front surface) and a second surface B (rear surface), which are perpendicular (orthogonal) to the third direction, of the vibrating arm 20 and stretching stress and the contracting stress need to be alternately generated in the vibrating arm 20.

In this embodiment, in order to generate the electric field Ex in the first direction, an inter digital transducer (IDT electrode) is arranged on at least one of the first surface A and the second surface B (one pair of main surfaces) of the vibrating arm 20 that face each other.

In the example shown in FIGS. 1C and 1D, an inter digital transducer is arranged on each of the first surface A and the second surface B of the vibrating arm 20. As shown in FIG. 1C, a first inter digital transducer arranged on the first surface A of the vibrating arm 20 has a first electrode 41a and a second electrode 41b.

The first electrode 41a and the second electrode 41b have opposing electrode portions (intersection finger electrode portion) in which electrode fingers face each other at a predetermined interval.

In addition, as shown in FIG. 1D, a second inter digital transducer arranged on the second surface B of the vibrating arm 20 has a first electrode 41c and a second electrode 41d.

Although not shown in FIG. 1D, similarly to the first surface A, the first electrode 41c and the second electrode 41d have opposing electrode portions in which electrode fingers face each other at a predetermined interval.

In addition, the first electrode 41a of the first inter digital transducer arranged on the first surface A and the first electrode 41c of the second inter digital transducer arranged on the second surface B are connected to each other, for example, through a through hole (not shown) that is arranged in the base portion 10, and a wiring extending from a first external connection terminal (not shown) such as a bonding pad arranged in the base portion 10 is connected to a common connection point thereof.

Similarly, the second electrode 41b of the first inter digital transducer arranged on the first surface A and the second electrode 41d of the second inter digital transducer arranged on the second surface B are connected to each other, for example, through a through hole that is arranged in the base portion 10, and a wiring extending from a second external connection terminal such as a bonding pad arranged in the base portion 10 is connected to a common connection point thereof.

A predetermined voltage is applied to each of the first external connection terminal and the second external connection terminal. Accordingly, between the first electrodes 41a and 41c and the second electrodes 41b and 41d, electric fields Ex1 and Ex2 used for generating the out-of-plane vibration of the vibrating arm 20 are generated.

As shown in FIG. 1D, the direction of the electric field Ex1 generated by the first inter digital transducer (the first electrode 41a and the second electrode 41b) arranged on the first surface A of the vibrating arm 20 and the direction of the electric field Ex2 generated by the second inter digital transducer (the first electrode 41c and the second electrode 41d) arranged on the second surface B of the vibrating arm 20 are opposite to each other.

Accordingly, in the example shown in FIG. 1D, stretching stress is generated for the first surface A, and contraction stress is generated for the second surface B. When the directions of the electric field Ex1 and the electric field Ex2 are reversed, contraction stress is generated for the first surface A, and stretching stress is generated for the second surface B.

Therefore, the vibrating arm 20 can be efficiently vibrated in the third direction (the Z-axis direction).

As described above, in this embodiment, the vibrating arm 20 vibrates in the third direction (the out-of-plane direction or the direction of the thickness of the vibrating arm) that is perpendicular to the first surface A and the second surface B.

In other words, work-mode vibration is excited in the vibrating arm 20. The resonance frequency of the vibrator element 100 in this case can be represented in the following Equation (3).

$$fn = α \cdot \frac{t}{{l}^{2}} \sqrt{\frac{E}{12 {ρ}_{res}}} \qquad ( 3 )$$

wherein α is a constant decided according to the supporting condition, t is the thickness of a vibrating arm, l is the length of the vibrating arm (arm length), E is the elastic constant of the vibrating arm (Young's modulus), and Pᵣₑₛ is the density of the vibrating arm.

As is apparent from the above-described Equation (3), as a condition for maintaining the resonance frequency fn to be constant, in a case where the arm length l of the vibrating arm 20 is shortened, the thickness t of the vibrating arm 20 is decreased (formed to be thinner). Accordingly, reasonable downsizing of the vibrating arm 20 can be realized.

In other words, by making out-of-plane vibration of the vibrating arm 20, a significant design parameter in a case where the vibrator element 100 is downsized while maintaining the resonance frequency of the vibrator element 100 is not the arm width w but the thickness t of the arm.

Here, the thickness t of the vibrating arm 20 can be controlled with high precision, for example, by adjusting the thickness of the quartz crystal plate configuring the vibrator element 100.

On the other hand, the arm width w of the vibrating arm 20 does not need to be decreased in correspondence with the scaling down of the arm length 1. Accordingly, the arm width w of the vibrating arm 20 can be maintained at a size level for which electrodes and wirings can be formed with high reliability. Therefore, in this embodiment a condition of “the width (arm width) w of the vibrating arm 20 >the thickness t of the vibrating arm” is satisfied.

In this embodiment, since the arm width w of the vibrating arm 20 can be set to an appropriate size, there is no concern about defective formation (disconnection, a contact, and the like) of wirings and electrodes. Therefore, the burden at the time of forming electrodes and wirings that is accompanied with miniaturization of the vibrator element 100 can be reduced.

In addition, since the thickness t of the vibrating arm 20 can be controlled with precision higher than that of the arm width w, the resonance frequency of the vibrator element 100 can be adjusted with high precision. For example, when a quartz crystal plate is cut out from a raw stone of quartz crystal or the like, the thickness t of the quartz crystal plate can be adjusted, and the thickness t can be also adjusted through a polishing process after the cutting out of the quartz crystal plate or the like.

In any of the cases, the parallelism between the first surface A and the second surface B of the quartz crystal plate can be controlled as high, and the thickness t can be controlled with high precision. This contributes to realization of a microscopic vibrator element 100 having high precision.

Example of Configuration of Inter digital transducer

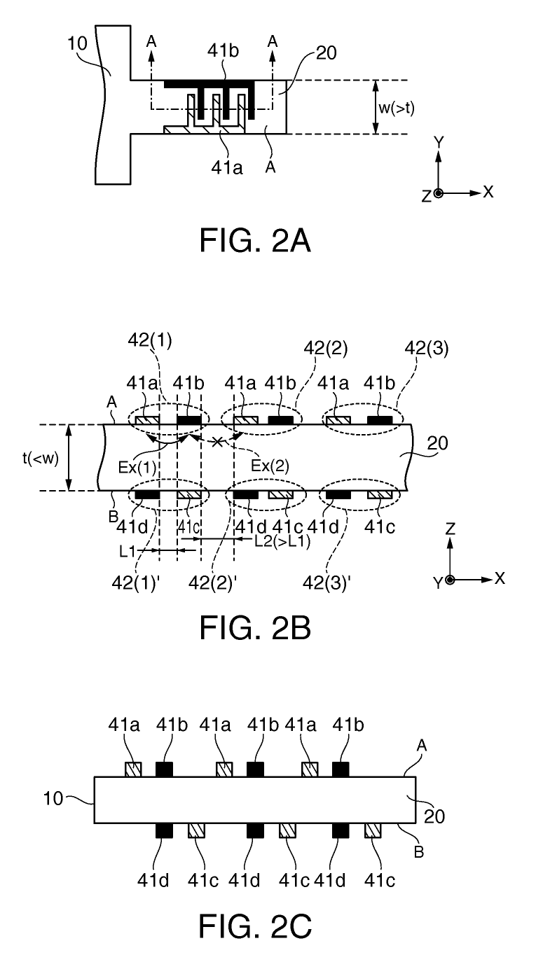

FIGS. 2A to 2C are diagrams showing an example of the configuration of the inter digital transducer. FIG. 2A is a plan view, and FIG. 2B is a cross-sectional view taken along line A-A shown in FIG. 2A.

As shown in FIGS. 2A and 2B, a first inter digital transducer (a first electrode 41a and a second electrode 41b) is arranged on a first surface A of a vibrating arm 20, and a second inter digital transducer (a first electrode 41c and a second electrode 41d) are arranged on a second surface B of the vibrating arm 20. Since the shape of each inter digital transducer is not a peculiar shape, the inter digital transducers can be formed in an easy manner. In addition, even in a case where the size thereof is decreased, there is an advantage that a problem of domination of an ineffective electric field does not occur can be acquired.

Here, the description will be presented with reference to FIG. 2B. The first inter digital transducer arranged on the first surface A has a first opposing portion 42(1) that is configured by one pair of electrode fingers (referred to as 41a and 41b for convenience of the description) that are arranged so as to face each other with being separated from each other by a predetermined distance L1, a second opposing portion 42(2) that is disposed so as to be adjacent to the first opposing portion 42(1) and is configured by one pair of electrode fingers (41a and 41b) that are arranged so as to face each other with being separated from each other by a predetermined distance L1, and a third opposing portion 42(3) that is disposed so as to be adjacent to the second opposing portion 42(2) and is configured by one pair of electrode fingers (41a and 41b) that are arranged so as to face each other with being separated from each other by a predetermined distance L1.

Each of the first opposing portion 42(1), the second opposing portion 42(2), and the third opposing portion 42(3) is arranged along the first direction (the X-axis direction) that is a direction of extension of the vibrating arm 20.

In addition, when a distance (a distance between the second opposing portion 42(2) and the third opposing portion 42(3)) between the first opposing portion 42(1) and the second opposing portion 42(2) is denoted by L2, a condition of “L1<L2” is satisfied.

In other words, the distance L2 between one electrode finger (for example, 41b of the first opposing portion 42(1)) and another electrode finger (for example, 41a of the second opposing portion 42(2)) adjacent to one side of the one electrode finger is longer than the distance L1 between the one electrode finger and another electrode finger (for example, 41a of the second opposing portion 42(2)) adjacent to the other side of the one electrode finger.

Similarly, the second inter digital transducer arranged on the second surface B has a first opposing portion 42(1)', a second opposing portion 42(2)', and a third opposing portion 42(3)'. Also for the second inter digital transducer arranged on the second surface B, a condition of “L1<L2” is satisfied.

The reason for the condition of “L1<L2” is as follows.

In the description below, the first opposing portion 42(1) and the second opposing portion 42(2) will be focused. In each of the first opposing portion 42(1) and the second opposing portion 42(2), an electric field (effective electric field) Ex(1) is generated between one pair of the electrode fingers (41a and 41b) facing each other, this electric field Ex(1) is applied to the vibrating arm 20, and contracting stress or stretching stress is generated in the vibrating arm 20.

Meanwhile, an electric field (ineffective electric field) Ex(2) is also generated between the electrode finger 41b of the first opposing portion 42(1) that is disposed on the second opposing portion side and the electrode finger 41a of the second opposing portion 42(2) that is disposed on the first opposing portion side.

In a case where the direction of the electric field Ex(1) that is generated in each of the first opposing portion 42(1) and the second opposing portion 42(2) and the direction of the electric field Ex(2) generated between the first opposing portion 42(1) and the second opposing portion 42(2) are opposite to each other, there is a problem in that a part of the effective electric field Ex(1) is negated by the ineffective electric field Ex(2).

Thus, in the example shown in FIG. 2B, the distance L2 between the electrode fingers of the first opposing portion 42(1) and the second opposing portion 42(2) is set to be longer than the distance L1 between the electrode fingers of each of the first opposing portion 42(1) and the second opposing portion 42(2).

Accordingly, a phenomenon that the ineffective electric field Ex(2) generated between the electrode finger 41b of the first opposing portion 42 (1) and the electrode finger 41a of the second opposing portion 42(2) is weakened, and a part of the effective electric field Ex(1) is negated by the ineffective electric field Ex(2) can be suppressed.

In addition, the arrangement of the inter digital transducers shown in FIG. 2B is an example, and the invention is not limited thereto.

Here, the description will be presented with reference to FIG. 2C.

FIG. 2C shows another example of the arrangement of inter digital transducers.

In the example shown in FIG. 2C, one electrode finger 41b (painted in black) of the first inter digital transducer disposed on the first surface A of the vibrating arm 20 and one electrode finger 41d (painted in black; having the same electric potential as the electrode finger 41b) of the second inter digital transducer disposed on the second surface B of the vibrating arm 20 are disposed so as to face each other.

For example, it is assumed that the electric potential polarity of each of the electrode finger 41b and the electrode finger 41d is “+”, and the electric potential polarity of each of the electrode finger 41a and the electrode finger 41c (diagonal lines) is “−”. The alignment of the polarities of the first inter digital transducer disposed on the first surface A is “+”, “−”, “+”, “−”, and “+” in the direction separated away from a base portion 10 with the electrode finger 41b being used as the base portion.

In addition, the alignment of the polarities of the second inter digital transducer disposed on the second surface B is “+”, “−”, “+”, “−”, “+” and “−” in the direction separated away from a base portion 10 with the electrode finger 41d facing the electrode finger 41b being used as the base portion.

As above, when the electrode fingers facing each other are used as the base portions, the alignment of the polarities of the first inter digital transducer disposed on the first surface A and the alignment of the polarities of the second inter digital transducer disposed on the second surface B coincide with each other.

In other words, the first inter digital transducer disposed on the first surface A and the second inter digital transducer disposed on the second surface B are disposed such that electrode fingers (here, 41a and 41d or 41b and 41c) having different polarities do not overlap each other in the third direction in the plan view.

By employing such an arrangement of the electrode fingers, an unnecessary electric field in the vertical direction (a direction connecting the first surface A and the second surface B; the thickness direction) between the first surface A and the second surface B can be suppressed.

Accordingly, occurrence of unnecessary distortion in the vibrating arm 20 can be suppressed. In addition, in the viewpoint of decreasing the unnecessary electric field, the power consumption can be suppressed.

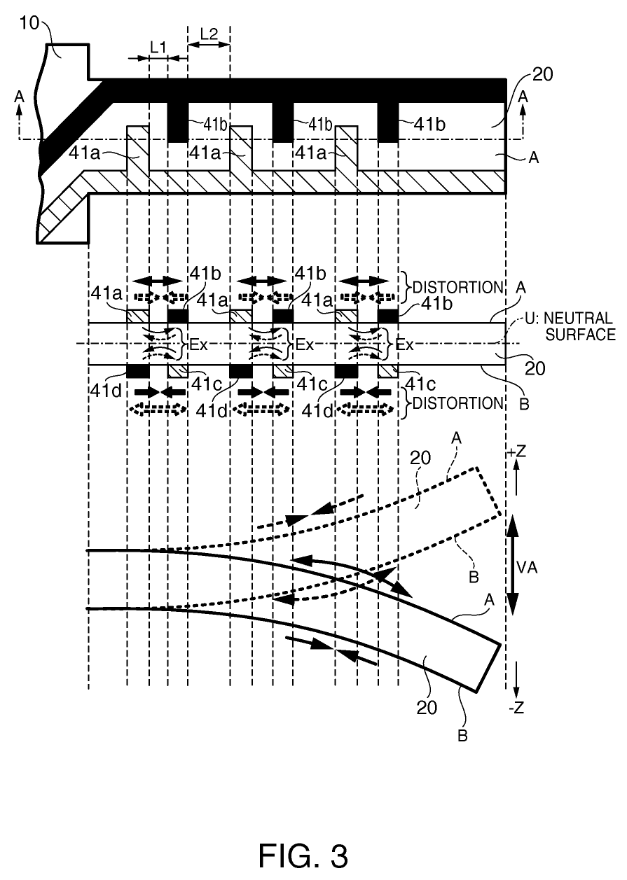

FIG. 3 is a schematic diagram illustrating the excitation of out-of-plane vibration of the vibrating arm.

In FIG. 3, a plan view of the vibrating arm 20 is shown on the upper side, a cross-sectional view of the vibrating arm taken along line A-A is shown at the center, and the appearance of the vibrating arm that vibrates in the out-of-plane direction is shown on the lower side.

As shown in the figure, distortion (stress) occurs on the first surface A and the second surface B of the vibrating arm in accordance with electric fields Ex applied in the first direction (the X-axis direction) caused by the inter digital transducers.

Here, in a case where contraction stress is generated on the first surface A, and stretching stress is generated on the second surface B, the vibrating arm 20 flexes in the positive third direction (+Z-axis direction) (a state denoted by a broken line on the lower side of FIG. 3).

On the other hand, in a case where stretching stress is generated on the first surface A, and contracting stress is generated on the second surface B, the vibrating arm 20 flexes in the negative third direction (−Z-axis direction) (a state denoted by a solid line on the lower side of FIG. 3).

The flexion in the positive third direction (+Z-axis direction) and the flexion in the negative third direction (−Z-axis direction) alternately occur. Accordingly, out-of-plane vibration (work-mode vibration) in the third direction (the Z-axis direction perpendicular to the first surface A and the second surface B) denoted by an arrow VA is constantly generated.

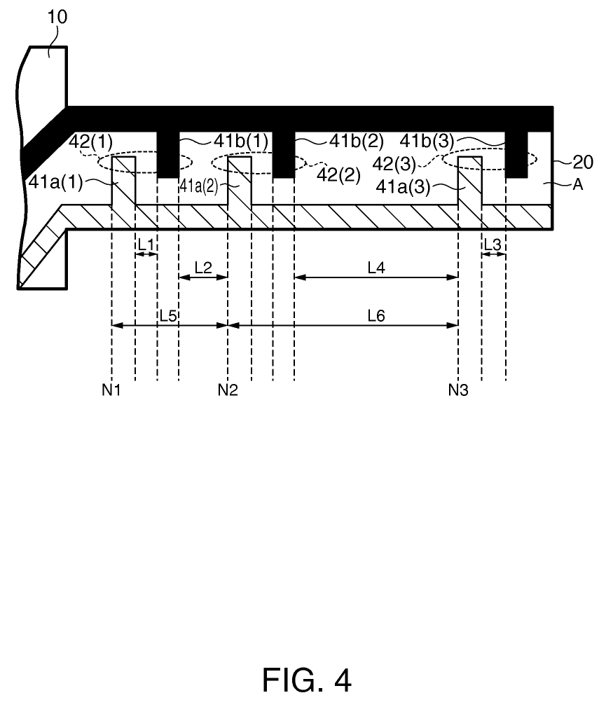

FIG. 4 is a diagram showing another example of the configuration of the inter digital transducer. In the example shown in FIG. 2B described above, distances between opposing portions of the inter digital transducer are equal. However, in the example shown in FIG. 4, distances of opposing portions differ in accordance with the distance from the base portion 10.

In FIG. 4, a first opposing portion 42(1), a second opposing portion 42(2), and a third opposing portion 42(3) of the first inter digital transducer disposed on the first surface A are separated away from the base portion 10 in the described order. When a gap between the first opposing portion 42(1) and the second opposing portion 42(2) is denoted by L2, and a distance between the second opposing portion 42(2) and the third opposing portion 42(3) is denoted by L4, a condition of “L2<L4” is satisfied. The reason for this is as follows.

In addition, when a gap between the electrode finger 41a(3) of the first electrode 41a and the electrode finger 41a (3) of the second electrode 41b of the third opposing portion 42(3) is denoted by L3, a condition of “L3<L4” is satisfied.

In order to generate out-of-plane vibration in the vibrating arm 20, distortion of stretching or contracting needs to occur on the main surface of the vibrating arm 20.

At this time, since the vibrating arm 20 vibrates in the out-of-plane direction with the base portion 10 as a fixed end used as a reference, distortion that is the most effective for the flexion of the vibrating arm is distortion occurring in a place (near the end of the base portion) that is close to the base portion 10.

Accordingly, distortion of a place (near front end portion) located far from the base portion 10 has a little influence on the flexion of the vibrating arm 20.

Based on this consideration, according to this embodiment, the gaps between three opposing portions included in the first inter digital transducer are changed in accordance with the distance from the base portion 10.

In other words, the gap L4 between the second opposing portion 42(2) and the third opposing portion 42(3) is set to be greater than the gap L2 between the first opposing portion 42(1) and the second opposing portion 42(2).

In the example shown in FIG. 4, when a distance between a first place N1 and a second place N2 is denoted by L5, a distance L6 between the second place N2 and a third place N3 is set to 2×L5.

Accordingly, the number of the opposing portions arranged along the direction of extension of the vibrating arm 20 can be set to be smaller than that of a case where the opposing portions are arranged so as to be equally spaced (particularly when the vibrating arm 20 is long, the effects of decreasing the number of the opposing portions prominently appear).

This represents that a total amount of the electric fields generated in the vibrating arm 20 decreases, and accordingly, an effect of reducing the power consumption can be acquired. On the other hand, even when an electric field in a place located far from the base portion 10 decreases, the degree of contribution of the electric field to the flexion of the vibrating arm 20 is low, and accordingly, out-of-plane vibration of the desired amplitude can be generated in the vibrating arm 20.

In other words, according to the above-described configuration, when a distance between one electrode finger (for example, 41b(1)) near the end of the base portion 10 of the vibrating arm 20 and another electrode finger (41a(1)) adjacent to one side of the one electrode finer described above is denoted by L1, and a distance between the one electrode finger described above and another electrode (41a(2)) adjacent to the other side of the one electrode described above is denoted by L2, L2 is greater than L1. In addition, a distance between one electrode finger (for example, 41a(3)) near the front end portion and another electrode finger (41b(3)) adjacent to one side of the one electrode described above is denoted by L3 and a distance between the one electrode finger described above and another electrode finger (41b(2)) adjacent to the other side of the one electrode finger described above is denoted by L4, L4 is greater than L3, and L4 is greater than L2.

In addition, it is preferable that L3 is equal to L1 or greater than L1.

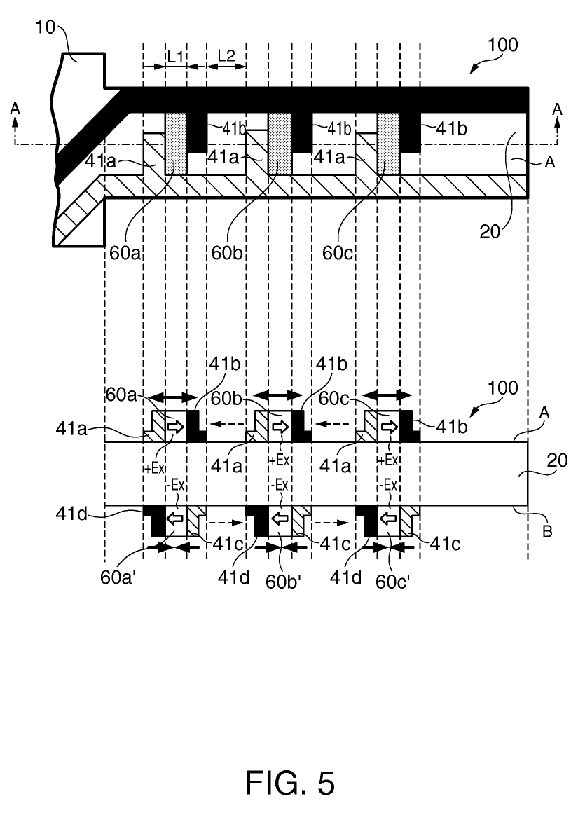

FIG. 5 is a diagram showing still another example of the configuration of the inter digital transducer. In FIG. 5, a plan view of a vibrating arm is shown on the upper side, and a cross-sectional view of the vibrating arm taken along line A-A is shown on the lower side.

As shown in the cross-sectional view of FIG. 5, on a first surface A of the vibrating arm 20, convex portions 60a to 60c are disposed. In addition, one pair of electrode fingers 41a and 41b that configure a first inter digital transducer and face each other are disposed on both side surfaces perpendicular to the first direction of the convex portions 60a to 60c with one of the convex portions 60a to 60c interposed therebetween.

Similarly, convex portions 60a′ to 60c′ are disposed on a second surface B of the vibrating arm 20. In addition, one pair of electrode fingers 41c and 41d that configure a second inter digital transducer and face each other are disposed on both side surfaces perpendicular to the first direction of the convex portions 60a′ to 60c′ with one of the convex portions 60a′ to 60c′ interposed therebetween.

According to this configuration, an unnecessary electric field (an electric field that is not required) decreases, and accordingly, the intensity of the electric field Ex generated between the electrode fingers (41a and 41b or 41c and 41d) facing each other can be increased. Accordingly, out-of-plane vibration can be excited more efficiently.

In addition, since the permittivity of the air is lower than the permittivity of quartz crystal that is the material of the vibrating arm 20, an ineffective electric field (a broken arrow in the figure) generated between opposing portions is weakened. In addition, since the inside of a decompressed package in which the vibrator element 100 is housed is close to a vacuum state, the ineffective electric field therein is further weakened.

Therefore, a phenomenon of negation of the effective electric field with the ineffective electric field is effectively reduced. This point also contributes to effective excitation of out-of-plane vibration and low power consumption of the vibrator element 100.

### Second Embodiment

In this embodiment, a plurality of vibrating arms extending in the first direction (the X-axis direction) from the base portion 10 is disposed. By disposing the plurality of vibrating arms and vibrating the vibrating arms, for example, in a dynamic balance, the out-of-plane vibration of the vibrating arms can be more stabilized.

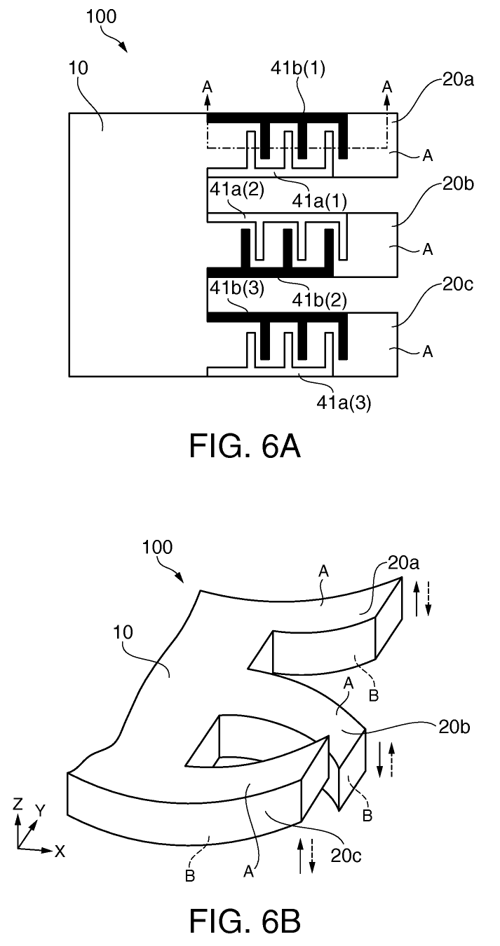

FIGS. 6A and 6B are diagrams showing an example in which three vibrating arms is arranged. FIG. 6A is a plan view, and FIG. 6B is a perspective view.

As shown in FIG. 6A, three vibrating arms (a first vibrating arm 20a, a second vibrating arm 20b, and a third vibrating arm 20c) extending from the base portion 10 in the first direction are disposed. In addition, inter digital transducers used for generating electric fields in the first direction are formed on at least one (preferably both) of a first surface A and a second surface B of each of the vibrating arms 20a to 20c.

A first inter digital transducer formed on the first surface A of the first vibrating arm 20a has a first electrode 41a(1) and a second electrode 41b(1).

A first inter digital transducer formed on the first surface A of the second vibrating arm 20b has a first electrode 41a(2) and a second electrode 41b(2).

A first inter digital transducer formed on the first surface A of the third vibrating arm 20c has a first electrode 41a(3) and a second electrode 41b(3).

Here, it is noteworthy that the arrangement of the electrodes of the second vibrating arm 20b is opposite to those of the first vibrating arm 20a and the third vibrating arm 20c. In other words, the direction of an electric field generated in the opposing portion of the first inter digital transducer of the second vibrating arm 20b is opposite to the directions of electric fields generated in the opposing portions of the first inter digital transducers of the first vibrating arm 20a and the third vibrating arm 20c.

Accordingly, as shown in FIG. 6B, the direction of displacement of out-of-plane vibration is the same (in-phase vibration) in the first vibrating arm 20a and the third vibrating arm 20c, and the direction of displacement of out-of-plane vibration in the second vibrating arm 20b is opposite (reverse-phase vibration) to those in the first vibrating arm 20a and the third vibrating arm 20c.

By employing such a configuration, the vibration of the first vibrating arm 20a to the third vibrating arm 20c of the vibrator element 100 has a dynamic balance in the second direction (the direction of the width of the vibrating arm) of the vibrator element 100 in the plan view, and has a dynamic balance in the third direction (the direction of the thickness of the vibrating arm) of the vibrator element 100.

Accordingly, excessive burden is not applied to the base portion 10 that supports the vibrating arms 20a to 20c, and leakage of vibration through the base portion 10 is suppressed.

In other words, in an example in which three vibrating arms 20a to 20c vibrating in the work mode are disposed, in order to stably continue the vibration in the work mode, it is preferable that the vibration of each vibrating arm 20a to 20c in the work mode is suppressed to leak to a support body that supports the base portion 10 through the base portion 10.

For example, the base portion 10 of the vibrator element 100 is fixed to a base member (a member that configures a part of the package or the like), for example, with an adhesive.

In a case where a work mode in which each of the vibrating arms 20a to 20c vibrates in the direction of the thickness t of each of the vibrating arms 20a to 20c, there may be problems such as disturbance in the vibration due to leakage from each vibrating arm 20a to 20c to the base portion 10, the occurrence of detachment of the adhesive, and the like.

In order to prevent the occurrence of such a situation, it is preferable that three vibrating arms 20a to 20c are arranged so as to be parallel to each other, the vibrating arms 20a and 20c arranged on both ends out of the vibrating arms 20a to 20c are vibrated in phase, and the vibrating arm 20b arranged at the center is vibrated in the reverse phase.

In the description as above, a case where the number of the vibrating arms is three has been presented. However, the number of the vibrating arms may be a multiple of three such as six, nine, or the like.

In other words, in a broad sense, m (m is a multiple of three) vibrating arms are arranged, and the m vibrating arms are respectively denoted by a first vibrating arm to an m-th vibrating arm. The first vibrating arm to the m-th vibrating arm are arranged parallel in the second direction (the Y-axis direction) in the ascending order of the value of m, and m vibrating arms are divided into three vibrating arm groups. Thus, the first vibrating arm to the (m/3)-th vibrating arm are grouped into first group vibrating arms, the {(m/3)+1}-th vibrating arm to the {(2m/3)}-th vibrating arms are grouped into second group vibrating arms, and the {(2m/3)+1} vibrating arm to the m-th vibrating arm are grouped into third group vibrating arms. Then, it can be defined that, “when the first group vibrating arms and the third group vibrating arms are displaced in the positive third direction (+Z-axis direction), the second group vibrating arms are displaced in the negative third direction (−Z-axis direction), and, when the first group vibrating arms and the third group vibrating arms are displaced in the negative third direction, the second group vibrating arms are displaced in the third direction”.

Also, in a case where a multiple of three vibrating arms are arranged in parallel, it is preferable that the vibrating groups disposed on both ends of the vibrating arm are vibrated in phase, and the vibrating arm groups at the center are vibrated in the reverse phase in consideration of the dynamic balance of the vibrating arm.

Described in detail, a case where the first group, the second group, and the third group vibrating arms are orderly disposed along the second direction will be considered. When a second area of the first group and third group vibrating arms is displaced in the positive third direction, a second area of the second vibrating arm at the center is displaced in the third direction. In this case, since the first group and the third group that are the groups disposed on both ends are displaced in phase, the balance is maintained in the second direction (horizontal direction) in the plan view.

In addition, since the first and third groups and the second group are displaced in the reverse phase, the stress (stress applied to the base portion supporting the vibrating arms of each group) caused by the displacement of each group in the third direction is offset, and the balance is maintained in the vibration direction (the vertical direction).

The number of the vibrating arms is not limited to a multiple of three and, for example, may be 2, 4, 5, 7, . . . n (here n is a natural number).

### Third Embodiment

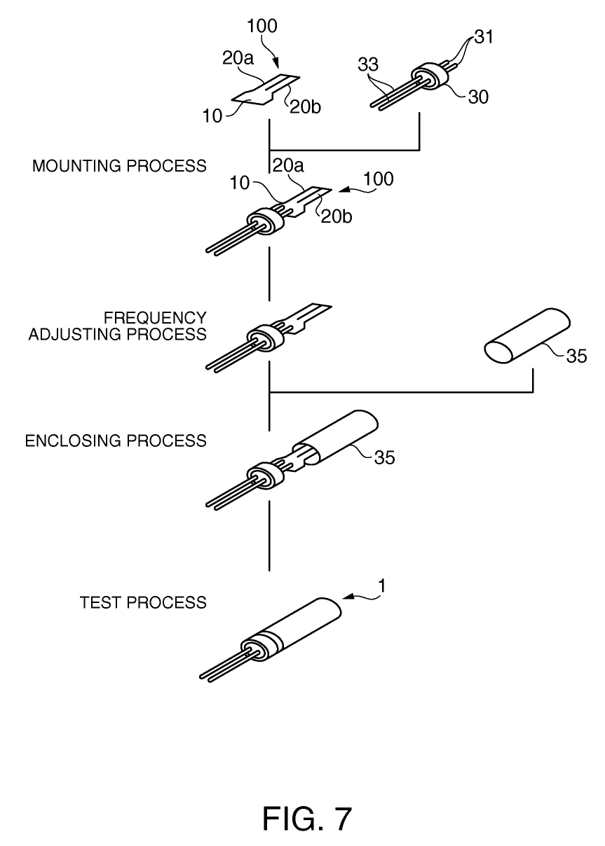

FIG. 7 is a diagram illustrating an example of a manufacturing process of a vibrator using the above-described vibrator element. The vibrator element 100 used in the example shown in FIG. 7 has a base portion 10 and two vibrating arms 20a and 20b.

Accordingly, the vibrator element 100 is configured as a tuning fork-type vibrator element. In addition, a plug 30 has an internal terminal 31 and an external terminal 33.

In a mounting process, the internal terminal 31 of the plug 30 is soldered to the base portion 10 of the vibrator element 100.

Next, in a frequency adjusting process, the resonance frequency of the vibrator element 100 is adjusted.

Next, in an enclosing process, the plug 30 is enclosed into a case 35 inside a vacuum chamber. The case 35 and the plug 30 configures an enclosing body (sealed package) as a housing body.

Next, through a test process, a vibrator 1 is completed.

According to this embodiment, since the vibrator 1 includes the vibrator element 100, a miniaturized vibrator that can be oscillated with high precision can be realized.

### Fourth Embodiment

In this embodiment, as a vibrator element, a vibrator element having a two-side supporting structure that supports the vibrating arm on both sides is used. Also in the vibrator element having the two-side supporting structure, similarly to the above-described embodiments, work-mode vibration can be excited.

However, in the case of the vibrator element having the two-side supporting structure, since the vibrating arm is supported on both sides, the vibration mode of the vibrating arm is different from the vibrator element in which only one side of the vibrating arm is supported.

In addition, in the vibrator element having the two-side supporting structure, from the viewpoint of excitation of out-of-plane vibration (work-mode vibration), it is preferable to employ an appropriate arrangement of electrodes.

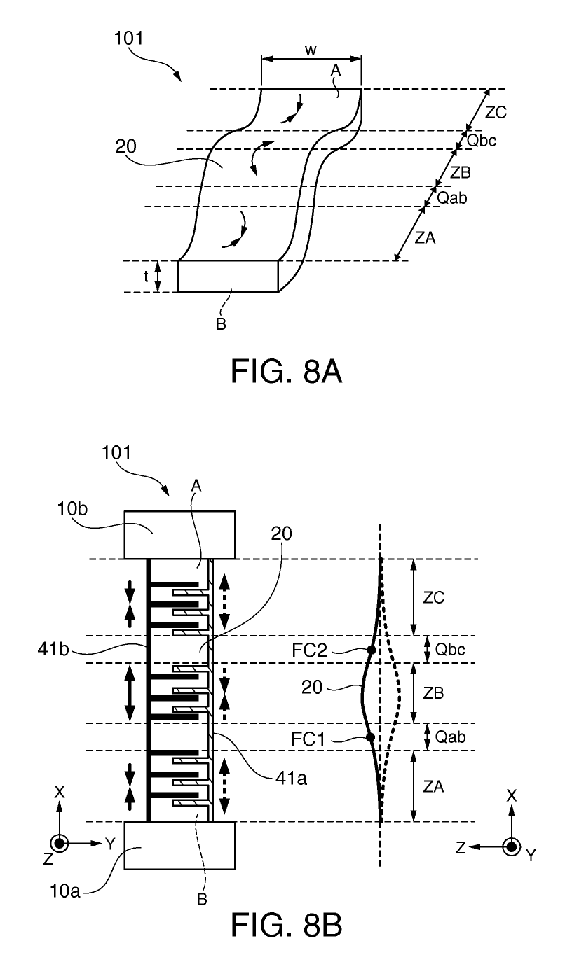

Hereinafter, detailed description will be followed with reference to FIGS. 8A to 10B.

FIGS. 8A and 8B are schematic diagrams illustrating examples of out-of-plane vibration of a vibrator element having a two-side supporting structure and the arrangement of electrodes.

FIG. 8A shows a vibration mode of the vibrating arm 20. In FIG. 8B, a left diagram is a plan view of the vibrator element, and a right diagram is a diagram showing the vibration mode of the vibrator element.

As shown in FIG. 8B, the vibrator element 101 having the two-side supporting structure includes a first base portion 10a and a second base portion 10b as the base portion. One end of the vibrating arm 20 is connected to the first base portion 10a, and the other end of the vibrating arm 20 is connected to the second base portion 10b.

The vibrator element 101, for example, can be used as a constituent element of an acceleration sensor or a pressure sensor.

As shown in FIG. 8A, one vibrating arm 20 (width w and thickness t (t<w)) is divided into a first area ZA, a second area ZB, a third area ZC, a first node area Qab that is disposed between the first area ZA and the second area ZB, and a second node area Qbc that is disposed between the second area ZB and the third area ZC.

When contracting stress, as denoted by arrows, is generated in the first area ZA and the third area ZC of the first surface A and the second surface B of the vibrating arm 20, stretching stress, denoted by arrows, is generated in the second area ZB of the first surface A and the second surface B of the vibrating arm 20.

To the contrary, when stretching stress is generated in the first area ZA and the third area ZC of the first surface A and the second surface B of the vibrating arm 20, contracting stress is generated in the second area ZB of the first surface A and the second surface B of the vibrating arm 20.

In other words, in order to vibrate the vibrating arm 20 in the direction of the thickness t (the third direction) with balance, the vibrating arm 20 is divided into the first area ZA, the second area ZB, and the third area ZC, the first node area Qab is disposed between the first area ZA and the second area ZB, and the second node area Qbc disposed between the second area ZB and the third area ZC.

As shown on the right side of FIG. 8B, each of the first node area Qab and the second node area Qbc includes vibration nodes FC1 and FC2. Described in detail, the vibration nodes FC1 and FC2 are points at which the differential coefficient of the second order is zero when the displacement of the vibrating arm 20 is acquired as a differential coefficient of the second order.

Then, when contraction occurs in the first area ZA and the third area ZC of the first surface A of the vibrating arm 20, stretching occurs in the second area ZB. Similarly, when stretching occurs in the first area ZA and the third area ZC, contacting occurs in the second area ZB. As a result, stable out-of-plane vibration can be realized.

As shown on the left side of FIG. 8B, a first inter digital transducer is formed on the first surface A of the vibrating arm 20. The first inter digital transducer has a first electrode 41a and a second electrode 41b.

The relative positional relationship between the electrode finger of the first electrode 41a and the electrode finger of the second electrode 41b in the second area ZB is opposite to the relative positional relationship between the electrode finger of the first electrode 41a and the electrode finger of the second electrode 41b in the first area ZA and the third area ZC.

Accordingly, the direction of the electric field generated in the second area ZB is opposite to the direction of the electric fields generated in the first area ZA and the third area ZC. The stress generated in each of the first area ZA, the second area ZB, and the third area ZC is denoted by a solid-line arrow and a broken-line arrow on the left side of FIG. 8B.

The vibration mode of the vibrating arm 20 denoted by a solid line on the right side of FIG. 8B corresponds to a case where stress denoted by a solid-line arrow is generated on the left side of FIG. 8B. Similarly, the vibration mode of the vibrating arm 20 denoted by a broken line corresponds to a case where stress denoted by a broken-line arrow is generated on the left side of FIG. 8B.

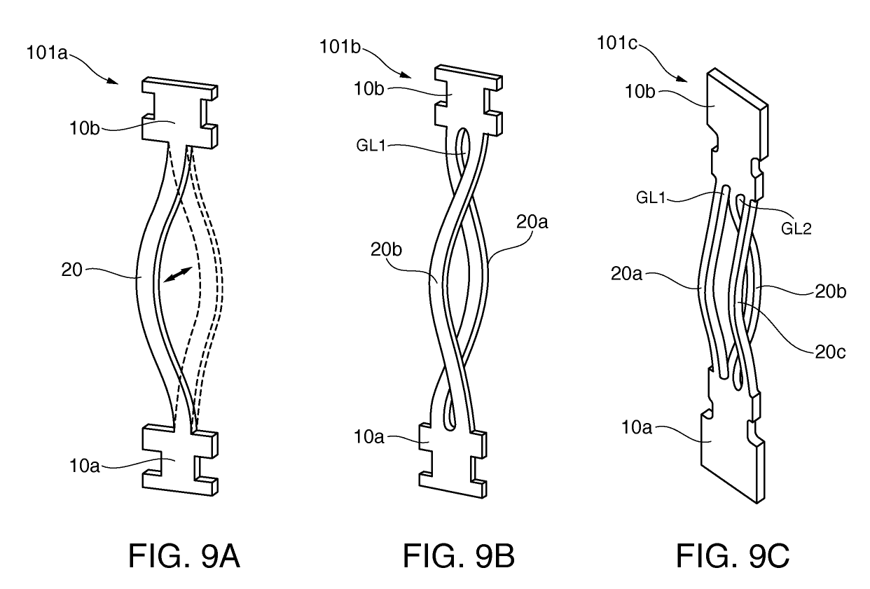

FIGS. 9A and 9C are diagrams showing examples of the configuration of the vibrator element having the two-side supporting structure. The vibrator element 101a shown in FIG. 9A has a first base portion 10a, a second base portion 10b, and one vibrating arm 20.

The vibrator element 101b shown in FIG. 9B has a first base portion 10a, a second base portion 10b, and two vibrating arms 20a and 20b.

The vibrator element 101c shown in FIG. 9C has a first base portion 10a, a second base portion 10b, and three vibrating arms 20a, 20b, and 20c.

Here, GL1 and GL2 represent groove portions between vibrating arms. In a case where n (here, n is a natural number equal to or greater than 2) vibrating arms are disposed, it is preferable that the vibrating arms are vibrated so as to be in a dynamic balance.

Accordingly, more stable out-of-plane vibration can be excited in the vibrating arms (20a to 20c, and the like) of the vibrator element having the two-side supporting structure.

In addition, a vibrator element having the two-side supporting structure that configures a tuning fork together with two or more vibrating arms and the base portion is referred to as a twin resonance tuning fork-type vibrator element (twin resonance tuning fork vibrator element).

In a case where three vibrating arms are disposed (the example shown in FIG. 9C), similarly to the example shown in FIGS. 6A and 6B, it is preferable that the vibrating arms 20a and 20c disposed on both ends are vibrated in phase, and the vibrating arm 20b disposed at the center is vibrated in a phase opposite to those of the vibrating arms 20a and 20c disposed on both ends. Here, the number of the vibrating arms is not limited to three, and may be a multiple of three (6, 9, . . . ).

In other words, in a broad sense, in a case where m (m is a multiple of three) vibrating arms are arranged, the m vibrating arms are respectively denoted by a first vibrating arm to an m-th vibrating arm. The first vibrating arm to the m-th vibrating arm are arranged parallel in the second direction in the ascending order of the value of m, and the m vibrating arms are divided into three vibrating arm groups. Thus, the first vibrating arm to the (m/3)-th vibrating arm are grouped into first group vibrating arms, the {(m/3)+1}-th vibrating arm to the {(2m/3)}-th vibrating arms are grouped into second group vibrating arms, and the {(2m/3)+1} vibrating arm to the m-th vibrating arm are grouped into third group vibrating arms. In addition, the third direction includes the positive third direction (+Z-axis direction) and the negative third direction (−Z-axis direction) that is opposite to the third direction. Then, it can be defined that, when contacting stress is generated in the first area ZA and the third area ZC of the first surface A (or the second surface B) of the first group vibrating arm and the third group vibrating arm, and stretching stress is generated in the second area ZB, stretching stress is generated in the first area ZA and the third area ZC of the first surface A (or the second surface B) of the second group vibrating arm, contacting stress is generated in the second area ZB, and stretching stress is generated on the first area ZA and the third area ZC of the first surface A (or the second surface B) of each of the first group vibrating arm and the third vibrating arm. In addition, it can be defined that, when contacting stress is generated in the second area ZB, contacting stress is generated in the first area ZA and the third area ZC of the first surface A (or the second surface B) of the second group vibrating arm, and stretching stress is generated in the second area ZB (see FIGS. 8A and 8B for each reference numeral).

Accordingly, for example, the vibrator element 101c is dynamically balanced in the second direction (the width direction of each vibrating arm) in the plan view and is dynamically balanced in the third direction (the direction of the width of the vibrating arm or the vibration direction) in the plan view.

Accordingly, excessive burden is not applied to the base portion (the first base portion 10a and the second base portion 10b) that supports the vibrating arms (20a to 20c), and leakage of vibration is suppressed.

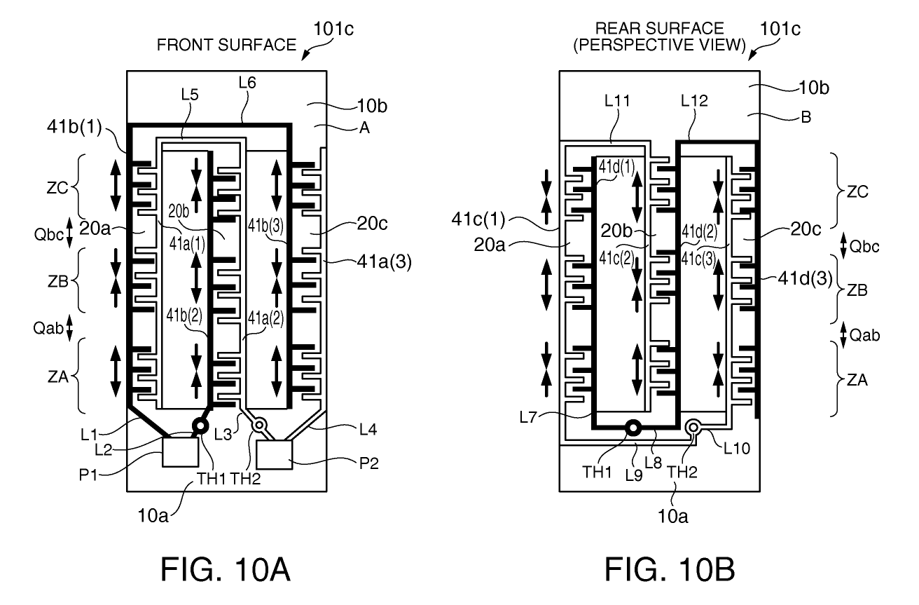

FIGS. 10A and 10B are diagrams showing examples of the arrangement of electrodes and wirings of a twin resonance tuning fork-type vibrator element having three vibrating arms.

FIG. 10A is a diagram showing the arrangement of electrodes the wirings on the surface of the vibrating arm. FIG. 10B is a diagram (a perspective view seen from the front surface side) showing the arrangement of electrodes and wirings on the surface of the vibrating arm. In FIGS. 10A and 10B, stress generated in each vibrating arm is denoted by thick-line arrows.

In other words, as described with reference to the example shown in FIGS. 8A and 8B, each of the vibrating arms 20a to 20c (the width w and the thickness t (t<w) of the vibrator element 101c is divided into the first area ZA, the second area ZB, the third area ZC, the first node area Qab is disposed between the first area ZA and the second area ZB, and the second node area Qbc disposed between the second area ZB and the third area ZC.

As shown in FIG. 10A, a first electrode 41a(1) and a second electrode 41b(1) that configure the first inter digital transducer are disposed on the surface (the first surface A) of the first vibrating arm 20a. Similarly to the example shown in FIGS. 8A and 8B, for example, when stretching stress is generated in the first area ZA and the third area ZC, contracting stress is generated in the second area ZB.

Similarly, a first electrode 41a(2) and a second electrode 41b(2) that configure the first inter digital transducer are disposed on the first surface A of the second vibrating arm 20b. For example, when contacting stress is generated in the first area ZA and the third area ZC, stretching stress is generated in the second area ZB.

Similarly, a first electrode 41a(3) and a second electrode 41b(3) that configure the first inter digital transducer are disposed on the first surface A of the third vibrating arm 20c. For example, when stretching stress is generated in the first area ZA and the third area ZC, contracting stress is generated in the second area ZB.

In FIG. 10A, L1 to L6 represent wirings formed on the first surface A of the vibrator element 101c. In addition, TH1 is a through hole that is used for connecting the second electrode of the first surface A and the second electrode of the rear surface (the second surface B), and TH2 is a through hole that is used for connecting the first electrode of the first surface A and the first electrode of the second surface B.

In addition, bonding pads P1 and P2 as external connection terminals are disposed on the first surface A of the first base portion 10a.

As shown in FIG. 10B, a first electrode 41c(1) and a second electrode 41d(1) configuring the second inter digital transducer are disposed on the second surface B of the first vibrating arm 20a. For example, when contracting stress is generated in the first area ZA and the third area ZC, stretching stress is generated in the second area ZB.

Similarly, a first electrode 41c(2) and a second electrode 41d(2) configuring the second inter digital transducer are disposed on the second surface B of the second vibrating arm 20b. For example, when stretching stress is generated in the first area ZA and the third area ZC, contracting stress is generated in the second area ZB.

Similarly, a first electrode 41c(3) and a second electrode 41d(3) configuring the second inter digital transducer are disposed on the second surface B of the third vibrating arm 20c. For example, when contracting stress is generated in the first area ZA and the third area ZC, stretching stress is generated in the second area ZB.

In addition, L7 to L12 shown in FIG. 10B represents wirings formed on the second surface B of the vibrator element 101c.

### Fifth Embodiment

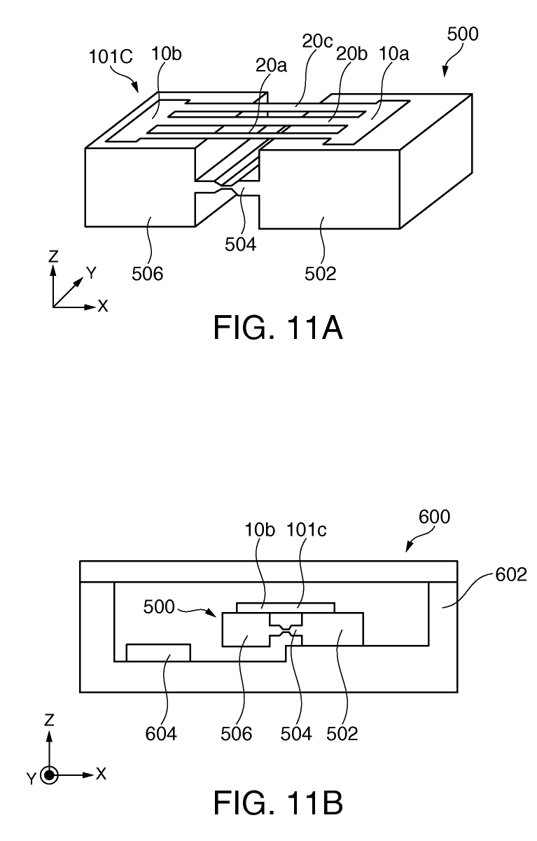

FIGS. 11A and 11B are diagrams showing an example of the structures of an acceleration sensor device and an acceleration sensor that use a twin resonance tuning fork-type vibrator element.

The acceleration sensor device 500 (an example of the sensor device) shown in FIG. 11A is configured by using a vibrator element 101c (the example shown in FIG. 9C) having three vibrating arms (20a to 20c).

The first base portion 10a of the vibrator element 101c is fixed to the first surface of the base portion 502, for example, with an adhesive. In addition, the second base portion 10b of the vibrator element 101c is fixed to the first surface of a pendulum portion (mass portion) 506, for example, with an adhesive.

The vibrating arms 20a to 20c of the vibrator element 101c are vibrated in the Z-axis direction at a predetermined frequency in a work mode.

The pendulum portion 506 is connected to the base portion 502, for example, through an elastic portion (including an elastic beam, spring, or the like) 504. When acceleration is applied in the Z-axis direction, the pendulum portion 506 is displaced in the Z-axis direction. As a result, distortion occurs in the vibrating arms 20a to 20c so as to change the frequency of vibrations. Thus, by detecting a change in the frequency, the magnitude of the acceleration can be detected (specified).

The acceleration sensor 600 shown in FIG. 11B has an acceleration sensor device 500 shown in FIG. 11A, an air-sealed package (a housing body) 602 that houses the acceleration sensor 500, and a physical amount detecting circuit 604. Inside the package 602, a decompressed state (for example, a vacuum state) is formed.

In this embodiment, the second base portion 10b of the vibrator element 101c is connected to the pendulum portion 506. However, a pressure sensor may be formed by fixing the base portions of the vibrator element 101c to a partition wall (the elastic portion in a broad sense) such as a silicon diaphragm having elasticity.

In other words, when the partition wall is deformed in the Z-axis direction in accordance with a pressure difference between two spaces separated by the partition wall, distortion occurs in the vibrating arms 20a to 20c so as to change the frequency of vibration. Thus, by detecting a change in the frequency, the change in the pressure can be measured.

As above, a senor that measures a physical mount can be realized by the above-described vibrator element (the twin resonance tuning fork-type vibrator element) in which the elastic potion displaced in accordance with a change in the physical amount of a measurement target or a mass portion connected to the elastic portion, and at least one base portion are connected to the elastic portion or the mass portion, and stretching or contracting occurs in at least one vibrating arm in the direction of extension of the vibrating arm in accordance with displacement of the elastic portion or the mass portion and a housing body that houses the vibrator element.

Accordingly, a miniaturized sensor (an acceleration sensor, a pressure sensor, or the like), which uses the miniaturized vibrator element that can be oscillated with high precision, having high precision can be realized.

As above, according to a vibrator element of at least an embodiment of the invention, by using out-of-pane vibration (vibration in the work mode), the vibrator element can be reasonably downsized, compared to a general case using in-plane vibration.

In other words, by decreasing the thickness (t) of the vibrating arm, downsizing can be responded, and the width w of the vibrating arm does not need to be decreased that much. Accordingly, the burden at the time of forming electrodes or wirings accompanied by miniaturization of the vibrator element can be reduced.

In addition, the material of the vibrator element is not limited to quartz crystal and may be a piezoelectric body such as lithium tantalite (LiTaO₃), lithium tetraborate (Li₂B₄O₇), lithium niobate (LiNbO₃), lead zirconate-titanate (PZT), zinc oxide (ZnO), aluminum nitride (AlN) or a semiconductor such as silicon (Si).

### Electronic Apparatus

Next, electronic apparatuses having the above-described vibrator element will be described. Here, diagrams are omitted.

The above-described vibrator element can be appropriately used as a sensing device or a timing device in an electronic apparatus such as a digital still camera, a video camera, a navigation system, a pointing device, a game controller, a cellular phone, an electronic book, a personal computer, a television set, a video recorder, a pager, an electronic organizer, a calculator, a word processor, a work station, a video phone, a POS terminal, or an apparatus having a touch panel. In any of the cases, an electronic apparatus having the advantages described in the above-described embodiments can be provided.

For example, the above-described vibrator element can provide an electronic apparatus having a miniaturized sensor having high precision.

The entire disclosure of Japanese Patent Application No. 2010-055446, filed Mar. 12, 2010 and No. 2010-271220, filed Dec. 6, 2010 are expressly incorporated by reference herein.

What is claimed is:

1. A vibrator element comprising:
a base portion;
a vibrating arm that extends in a first direction from the base portion, has a width in a second direction perpendicular to the first direction in the plan view, and has a thickness in a third direction perpendicular to the first direction and the second direction; and
an inter digital transducer, in which electrode fingers are arranged in the first direction, disposed at least one of a first surface, which is perpendicular to the third direction, and a second surface, which faces the first surface, of the vibrating arm,
wherein the vibrating arm is vibrated in the third direction by stretching or contacting the vibrating arm in the first direction by using an electric field in the first direction that is generated by the inter digital transducer.

2. The vibrator element according to claim 1, wherein, when the width of the vibrating arm is w, and the thickness is t, a condition of “w>t” is satisfied.

3. The vibrator element according to claim 1,
wherein quartz crystal is used for the vibrator element, and
wherein the first direction is an X-axis direction of the crystal axis of the quartz crystal, the second direction is a Y-axis direction of the crystal axis of the quartz crystal, and the third direction is a Z-axis direction of the crystal axis of the quartz crystal.

4. A vibrator element according to claim 1,
wherein, when a distance between one electrode finger and another electrode finger adjacent to one side of the electrode finger is L1, and a distance between the electrode finger and another electrode finger adjacent to the other side of the electrode finger is L2, L2 is greater than L1 in the inter digital transducer.

5. The vibrator element according to claim 1,
wherein, when a distance between one electrode finger disposed near an end of the base portion of the vibrating arm and another electrode finger adjacent to one side of the one electrode is L1, and a distance between the one electrode finger and another electrode finger adjacent to the other side of the electrode finger is L2, L2 is greater than L1,
wherein, when a distance between one electrode finger disposed near a front end portion of the vibrating arm and another electrode finger adjacent to one side of the one electrode is L3, and a distance between the one electrode finger and another electrode finger adjacent to the other side of the electrode finger is L4, L4 is greater than L3, and
wherein L4 is greater than L2.

6. The vibrator element according to claim 1,
wherein the inter digital transducer is disposed on the first surface and the second surface, and
wherein the directions of the electric fields are opposite to each other in a first inter digital transducer disposed on the first surface and in a second inter digital transducer disposed on the second surface.

7. The vibrator element according to claim 6,
wherein, in the first inter digital transducer and the second inter digital transducer, the electrode fingers having different polarities do not overlap each other in the third direction in the plan view.

8. The vibrator element according to claim 1,
wherein a concave portion is disposed on at least one of the first surface and the second surface of the vibrating arm, and
wherein the electrode fingers configuring the inter digital transducer are disposed on each of both side surfaces of the convex portions that are perpendicular to the first direction.

9. The vibrator element according to claim 1,
wherein a plurality of the vibrating arms is disposed.

10. The vibrator element according to claim 1,
wherein the base portion includes a first base portion and a second portion, and
wherein one end of the vibrating arm and the first base portion are connected to each other, and the other end of the vibrating arm and the second base portion are connected to each other.

11. A vibrator comprising:
the vibrator element according to claim 1; and
a housing body that houses the vibrator element.

12. A sensor comprising:
the vibrator element according to claim 1.

13. An electronic apparatus comprising:
the vibrator element according to claim 1.
